(19) United States
(12) Patent Application Publication
(10) Pub. No.: US 2024/0324435 A1
(43) Pub. Date: Sep. 26, 2024

(54) APPARATUS AND METHOD FOR MANUFACTURING DISPLAY DEVICE, AND MASK ASSEMBLY

(71) Applicant: Samsung Display Co., Ltd., Yongin-si (KR)

(72) Inventors: Jeongkuk Kim, Yongin-si (KR); Sungsoon Im, Yongin-si (KR); Wonje Cho, Yongin-si (KR)

(73) Assignee: Samsung Display Co., Ltd., Yongin-si (KR)

(21) Appl. No.: 18/480,544

(22) Filed: Oct. 4, 2023

(30) Foreign Application Priority Data
Mar. 24, 2023 (KR) 10-2023-0038981
Apr. 21, 2023 (KR) 10-2023-0052821

(51) Int. Cl. H10K 71/20; G03F 7/00; G09G 3/3233; H10K 59/12

(52) U.S. Cl. CPC H10K 71/233; G03F 7/70058; G09G 3/3233; H10K 59/1201; G09G 2300/0426; G09G 2300/0842

(57) ABSTRACT

An apparatus for manufacturing a display device includes a mask assembly arranged inside a chamber and facing a display substrate, a magnetic force portion arranged inside the chamber and applying a magnetic force to the mask assembly, and a deposition source which is arranged inside the chamber, faces the mask assembly, and supplies a deposition material that passes through the mask assembly and is deposited on the display substrate. The mask assembly includes a first mask layer including a first mask opening, and a second mask layer disposed on the first mask layer. The second mask layer includes a metal layer including a metal opening corresponding to the first mask opening, and an inorganic layer including an inorganic opening corresponding to the first mask opening and the metal opening. In a plan view, a width of the metal opening is greater than a width of the inorganic opening.

### CROSS-REFERENCE TO RELATED APPLICATIONS

This application claims priority to and benefits of Korean Patent Application Nos. 10-2023-0038981 under 35 U.S.C. § 119, filed on Mar. 24, 2023, and 10-2023-0052821 under 35 U.S.C. § 119, filed on Apr. 21, 2023, in the Korean Intellectual Property Office (KIPO), the entire contents of which are incorporated herein by reference.

### BACKGROUND

### 1. Technical Field

Embodiments relate to an apparatus and a method for manufacturing a display device, and a mask assembly.

### 2. Description of the Related Art

Display apparatuses visually display data. Display apparatuses may provide images by using light-emitting diodes. Display apparatuses are used for various purposes. Thus, various designs have been attempted to improve the quality of display apparatuses.

### SUMMARY

Embodiments include a mask assembly which has magnetic properties and in which an area contacting a display substrate is reduced.

However, this objective is an example, and objectives of the disclosure are not limited thereto.

Additional aspects will be set forth in part in the description which follows and, in part, will be apparent from the description, or may be learned by practice of the presented embodiments of the disclosure.

According to an embodiment, an apparatus for manufacturing a display device may include a chamber, a mask assembly arranged inside the chamber and facing a display substrate, a magnetic force portion arranged inside the chamber and applying a magnetic force to the mask assembly, and a deposition source which is arranged inside the chamber, faces the mask assembly, and supplies a deposition material that passes through the mask assembly and is deposited on the display substrate. The mask assembly may include a first mask layer including a first mask opening, and a second mask layer disposed on the first mask layer. The second mask layer may include a metal layer including a metal opening corresponding to the first mask opening, and an inorganic layer including an inorganic opening corresponding to the first mask opening and the metal opening. In a plan view, a width of the metal opening may be greater than a width of the inorganic opening.

The inorganic layer may cover the metal layer.

A portion of the metal layer may be exposed from the inorganic layer.

The inorganic layer may include a first inorganic portion, and a second inorganic portion disposed on the first inorganic portion, and the inorganic opening may include a first inorganic opening arranged in the first inorganic portion, and a second inorganic opening arranged in the second inorganic portion.

In a plan view, an area of the second inorganic opening may be greater than an area of the first inorganic opening.

In a cross-sectional view, a width of the first inorganic opening may gradually decrease in a direction toward the second inorganic portion.

According to an embodiment, a method of manufacturing a display device may include arranging a display substrate inside a chamber, arranging a mask assembly inside the chamber, applying, by a magnetic force portion, a magnetic force to the mask assembly, and supplying, by a deposition source, a deposition material toward the mask assembly. The arranging of the mask assembly may include arranging, on a first mask layer, a metal layer including a metal opening, and arranging, on the metal layer, an inorganic layer including an inorganic opening. In a plan view, a width of the metal opening may be greater than a width of the inorganic opening.

The arranging of the inorganic layer may include arranging a photoresist layer on the first mask layer, arranging the inorganic layer on the photoresist layer, etching the inorganic layer, and removing the photoresist layer.

The arranging of the photoresist layer may include arranging a photoresist material on the first mask layer, arranging, on the photoresist material, a photomask including a photomask opening, exposing the photoresist material to light through the photomask opening, and developing the photoresist material into the photoresist layer.

The arranging of the photoresist layer may further include baking the photoresist material.

The inorganic layer may cover the metal layer.

A portion of the metal layer may be exposed from the inorganic layer.

The inorganic layer may include a first inorganic portion, and a second inorganic portion disposed on the first inorganic portion, and the inorganic opening may include a first inorganic opening arranged in the first inorganic portion, and a second inorganic opening arranged in the second inorganic portion.

In a plan view, an area of the second inorganic opening may be greater than an area of the first inorganic opening.

In a cross-sectional view, a width of the first inorganic opening may gradually decrease in a direction toward the second inorganic portion.

According to an embodiment, a mask assembly may include a first mask layer including a first mask opening, and a second mask layer disposed on the first mask layer. The second mask layer may include a metal layer including a metal opening corresponding to the first mask opening, and an inorganic layer including an inorganic opening corresponding to the first mask opening and the metal opening. In a plan view, a width of the metal opening may be greater than a width of the inorganic opening.

The inorganic layer may include a first inorganic portion, and a second inorganic portion disposed on the first inorganic portion, and the inorganic opening may include a first inorganic opening arranged in the first inorganic portion, and a second inorganic opening arranged in the second inorganic portion.

In a plan view, an area of the second inorganic opening may be greater than an area of the first inorganic opening.

In a cross-sectional view, a side of the first inorganic opening may be inclined.

The inorganic layer may cover the metal layer.

Other aspects, features, and advantages than the above would be clear from the accompanying drawings, the claims, and the detailed description of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic cross-sectional view of an apparatus for manufacturing a display device, according to an embodiment;

FIG. 2 is a schematic cross-sectional view of a mask assembly according to an embodiment;

FIG. 3 is a schematic plan view of a portion of a second mask layer according to an embodiment;

FIGS. 4 to 12 are schematic cross-sectional views of a mask assembly for describing a method of manufacturing a display device, according to an embodiment;

FIG. 13 is a schematic perspective view of a display device according to an embodiment;

FIG. 14 is a schematic cross-sectional view of a display device according to an embodiment;

FIG. 15 is a schematic plan view of a display panel according to an embodiment;

FIG. 16 is a schematic diagram of an equivalent circuit of a pixel included in a display device according to an embodiment; and

FIG. 17 is a schematic cross-sectional view of a display device according to an embodiment.

### DETAILED DESCRIPTION OF THE EMBODIMENTS

Reference will now be made in detail to embodiments, examples of which are illustrated in the accompanying drawings, wherein like reference numerals refer to like elements throughout. In this regard, the disclosure may have different forms and should not be construed as being limited to the descriptions set forth herein. Accordingly, the embodiments are merely described below, by referring to the figures, to explain aspects of the description. As used herein, the term “and/or” includes any and all combinations of one or more of the associated listed items. Throughout the disclosure, the expression “at least one of a, b, or c” indicates only a, only b, only c, both a and b, both a and c, both b and c, all of a, b, and c, or variations thereof.

As the disclosure allows for various changes and numerous embodiments, certain embodiments will be illustrated in the drawings and described in detail in the written description. Hereinafter, effects and features of the disclosure and a method for accomplishing them will be described more fully with reference to the accompanying drawings, in which embodiments of the disclosure are shown. This disclosure may, however, be embodied in many different forms and should not be construed as limited to the embodiments set forth herein.

Embodiments of the disclosure will be described below in more detail with reference to the accompanying drawings. Those elements that are the same or are in correspondence are rendered the same reference numeral regardless of the figure number, and redundant descriptions are omitted.

In an embodiment below, terms, such as “first” and “second,” are used herein merely to describe a variety of elements, but the elements are not limited by the terms. Such terms are used only for the purpose of distinguishing one element from another element.

In an embodiment below, an expression used in the singular encompasses the expression of the plural, unless it has a clearly different meaning in the context.

In an embodiment below, terms, such as “include” or “comprise,” may be construed to denote a certain characteristic or element, or a combination thereof, but may not be construed to exclude the existence of or a possibility of addition of one or more other characteristics, elements, or combinations thereof.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

Sizes of elements in the drawings may be exaggerated or reduced for convenience of explanation. In other words, since sizes and thicknesses of elements in the drawings are arbitrarily illustrated for convenience of explanation, the following embodiments are not limited thereto.

In the following embodiments, the x-axis, the y-axis, and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

When a certain embodiment may be implemented differently, a specific process order may be performed differently from the described order. For example, two consecutively described processes may be performed substantially at the same time or performed in an order opposite to the described order.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

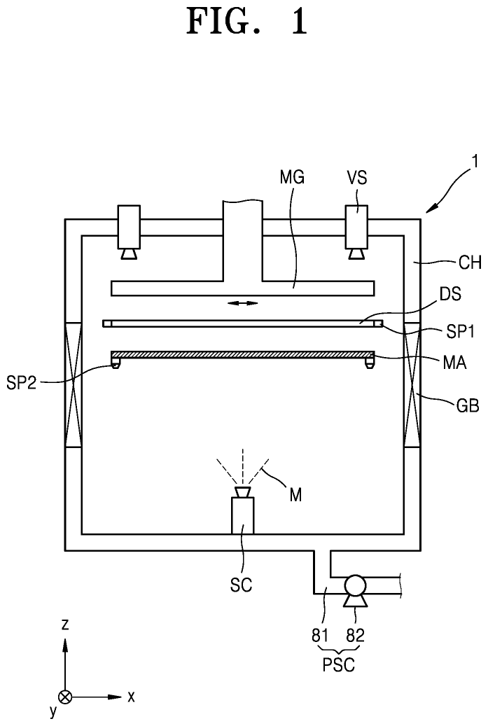

FIG. 1 is a schematic cross-sectional view of an apparatus 1 for manufacturing a display device, according to an embodiment.

The apparatus 1 for manufacturing a display device may include a chamber CH, a first support portion SP1, a second support portion SP2, a mask assembly MA, a deposition source SC, a magnetic force portion MG, a vision portion VS, and a pressure adjustment portion PSC.

The chamber CH may have a space formed therein, and may store a display substrate DS and the mask assembly MA. A portion of the chamber CH may be formed to be opened, and a gate valve GB may be installed in the opened portion of the chamber CH. The opened portion may be opened or closed according to an operation of the gate valve GB.

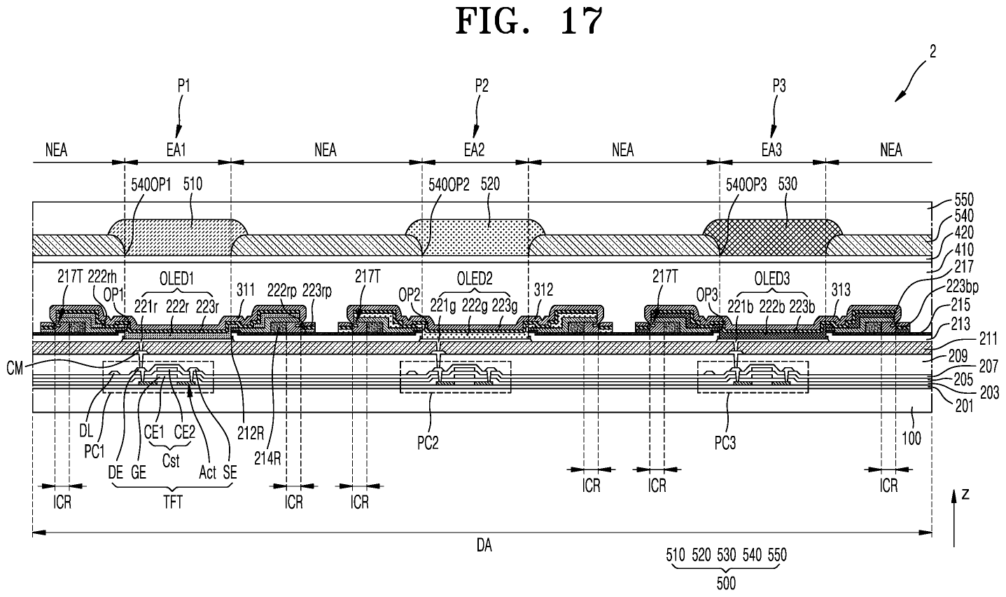

In an embodiment, the display substrate DS may be a display substrate DS of the display device being manufactured, in which at least one of an organic layer, an inorganic layer, and a metal layer is deposited on a substrate 100 (see, FIG. 17) described below. In another embodiment, the display substrate DS may be a substrate 100 on which none of the organic layer, the inorganic layer, and the metal layer is deposited yet.

The first support portion SP1 may support the display substrate DS. The first support portion SP1 may have a plate shape fixed to the inside of the chamber CH. In another embodiment, the display substrate DS may be seated on the first support portion SP1, and the first support portion SP1 may be of a shuttle type capable of linearly moving inside and outside the chamber CH. In another embodiment, the first support portion SP1 may include an electrostatic chuck or an adhesive chuck arranged in the chamber SP1 to be fixed to the chamber CH or to be able to move inside the chamber CH.

The second support portion SP2 may support the mask assembly MA. The second support portion SP2 may be arranged inside the chamber CH. The second support portion SP2 may fine-adjust a position of the mask assembly MA. The second support portion SP2 may have an additional driving unit or an additional alignment unit so as to move the mask assembly MA in a separate direction.

In another embodiment, the second support portion SP2 may be of a shuttle type, and the mask assembly MA may be seated on the second support portion SP2, and the second support portion SP2 may transfer the mask assembly MA. For example, the second support portion SP2 may move to the outside of the chamber CH, have the mask assembly MA seated thereon, and enter the chamber CH from the outside the chamber CH.

In an embodiment, the first support portion SP1 and the second support portion SP2 may be integral with each other, and the first support portion SP1 and the second support portion SP2 may each include a movable shuttle. Each of the first support portion SP1 and the second support portion SP2 may include a structure that fixes the mask assembly MA and the display substrate DS in a state in which the display substrate DS is seated on the mask assembly MA, and may allow the display substrate DS and the mask assembly MA to linearly move at the same time.

However, for convenience of description, a structure in which the first support portion SP1 and the second support portion SP2 are formed to be separated from each other and arranged at different positions, and a structure in which the first support portion SP1 and the second support portion SP2 are arranged inside the chamber CH are described in detail below.

The mask assembly MA may be arranged to face the display substrate DS in the chamber CH. A deposition material M may be deposited on the display substrate DS through the mask assembly MA.

The deposition source SC may be arranged to face the mask assembly MA, and may supply the deposition material M to the display substrate DS so as to deposit the deposition material M on the display substrate DS through the mask assembly MA. The deposition source SC may apply heat to the deposition material M to evaporate or sublimate the deposition material M. The deposition source SC may be arranged in the chamber CH and fixed to the inside of the chamber CH or linearly move in one direction.

The magnetic force portion MG may be arranged in the chamber CH to face the display substrate DS and/or the mask assembly MA. The magnetic force portion MG may apply pressure to the mask assembly MA toward the display substrate DS by applying a magnetic force to the mask assembly MA.

The vision portion VS may be arranged in the chamber CH and may detect positions of the display substrate DS and the mask assembly MA. The vision portion VS may include a camera for photographing the display substrate DS and the mask assembly MA. The positions of the display substrate DS and the mask assembly MA may be identified based on an image captured by the vision portion VS, and deformation of the mask assembly MA may be identified. Based on the image, the position of the display substrate DS in the first support portion SP1 may be fine-adjusted, or the position of the mask assembly MA in the second support portion SP2 may be fine-adjusted. An embodiment that the positions of the display substrate DS and the mask assembly MA are aligned by fine-adjusting the position of the mask assembly MA in the second support portion SP2 is described in detail below.

The pressure adjustment portion PSC may be connected to the chamber CH and may adjust a pressure inside the chamber CH. For example, the pressure adjustment portion PSC may adjust the pressure inside the chamber CH to be equal or similar to the atmospheric pressure. The pressure adjustment portion PSC may adjust the pressure inside the chamber CH to be equal or similar to a vacuum state.

The pressure adjustment portion PSC may include a connection pipe 810 connected to the chamber CH, and a pump 82 installed in the connection pipe 81. According to an operation of the pump 82, external air may be introduced into the chamber CH through the connection pipe 81, or gas inside the chamber CH may be exhausted to the outside through the connection pipe 81.

To describe a method of manufacturing a display device (not shown) by using the apparatus 1 for manufacturing a display device as described above, first, a display substrate DS may be prepared.

The pressure adjustment portion PSC may maintain the inside of the chamber CH to be equal or similar to the atmospheric pressure, and the gate valve GB may be operated to open the opened portion of the chamber CH.

The display substrate DS may be loaded into the chamber CH from the outside of the chamber CH. The display substrate DS may be loaded into the chamber CH in various ways. For example, the display substrate DS may be loaded into the chamber CH from the outside of the chamber CH through a robot arm or the like arranged outside the chamber CH. In another embodiment, in case that the first support portion SP1 is of a shuttle type, the first support portion SP1 may be taken out of the chamber CH from the inside of the chamber CH, and the display substrate DS may be seated on the first support portion SP1 by an additional robot arm or the like arranged outside the chamber CH, and the first support portion SP1 may be loaded into the chamber CH from the outside of the first support portion SP1.

The mask assembly MA may be arranged in the chamber, as described above. In another embodiment, the mask assembly MA may be loaded into the chamber CH from the outside of the chamber CH with a method identical or similar to the display substrate DS.

In case that the display substrate DS is loaded into the chamber CH, the display substrate DS may be seated on the first support portion SP1. The vision portion VS may photograph the positions of the display substrate DS and the mask assembly MA. Based on an image captured by the vision portion VS, the positions of the display substrate DS and the mask assembly MA may be identified. The apparatus 1 for manufacturing a display device may have an additional controller (not shown) and identify the positions of the display substrate DS and the mask assembly MA.

In case that the identification of the positions of the display substrate DS and the mask assembly MA is completed, the second support portion SP2 may fine-adjust the positions of the mask assembly MA.

The deposition source SC may supply the deposition material M toward the mask assembly MA, and the deposition material M passing through the mask assembly MA may be deposited on the display substrate DS. The deposition source SC may move parallel to the display substrate DS and the mask assembly MA, or the display substrate DS and the mask assembly MA may move parallel to the deposition source SC. In other words, the deposition source SC may move in relation to the display substrate DS and the mask assembly MA. The pump 82 may absorb gas inside the chamber CH and discharge the absorbed gas to the outside, to maintain the pressure inside the chamber CH to be in an identical or similar form to vacuum.

As described above, the deposition material M supplied from the deposition source SC may be deposited on the display substrate DS through the mask assembly MA, and accordingly, at least one of multiple layers, e.g., an organic layer, an inorganic layer, and a metal layer, of the display device below may be formed.

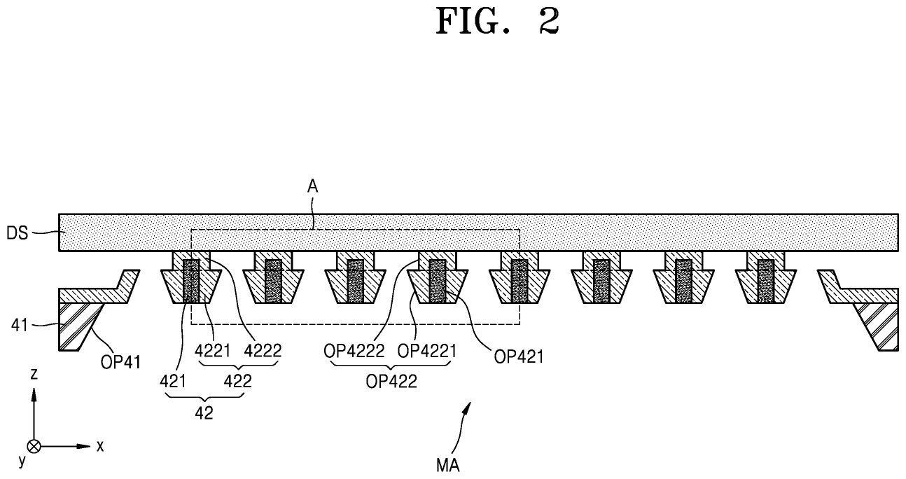

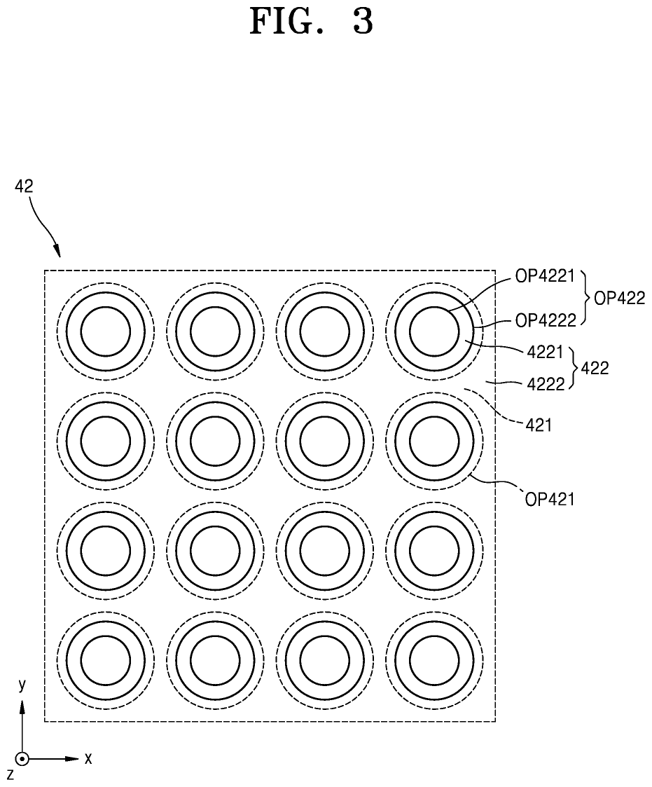

FIG. 2 is a schematic cross-sectional view of a mask assembly MA according to an embodiment, and FIG. 3 is a schematic plan view of a portion of a second mask layer 42 according to an embodiment. FIG. 3 is a plan view of region A in FIG. 2.

Referring to FIGS. 2 and 3, the mask assembly MA may include a first mask layer 41 and the second mask layer 42.

A first mask opening OP41 may be arranged in the first mask layer 41 to allow the deposition material M (see FIG. 1) to pass therethrough. An inner circumferential surface may be formed in the first mask layer 41 by the first mask opening OP41. The first mask opening OP41 may be arranged in a center portion of the first mask portion 41. A center portion of the second mask layer 42 may be exposed through the first mask opening OP41 of the first mask layer 41. Referring to FIG. 2, the inner circumferential surface of the first mask layer 41 may be inclined toward the second mask layer 42. However, the disclosure is not limited thereto, and the inner circumferential surface of the first mask layer 41 may be perpendicular to the second mask layer 42.

The first mask layer 41 may include a silicon material. For example, the first mask layer 41 may include at least one of silicon oxide (SiOₓ), silicon nitride (SiNₓ), and silicon oxynitride (SiOₓN_{y}).

The second mask layer 42 may be disposed on the first mask layer 41. The second mask layer 42 may be supported by the first mask layer 41. The second mask layer 42 may include a metal layer 421 and an inorganic layer 422.

The metal layer 421 may be disposed on the first mask layer 41. The metal layer 421 may have magnetic properties. For example, the metal layer 421 may include at least one of aluminum (Al), copper (Cu), titanium (Ti), and molybdenum (Mo).

The metal layer 421 may be supported by the inorganic layer 422 on the first mask layer 41. A metal opening OP421 corresponding to the first mask opening OP41 may be arranged in the metal layer 421. The metal opening OP421 may overlap the first mask opening OP41 in a plan view. The metal layer 421 may include multiple metal openings OP421. For example, as shown in FIG. 3, the openings OP421 may be arranged in a first direction (e.g., a y-axis direction) and a second direction (e.g., an x-axis direction).

The inorganic layer 422 may be disposed on the first mask layer 41 and the metal layer 421. The inorganic layer 422 may be supported by the first mask layer 41. The inorganic layer 422 may include at least one of SiOₓ, SiNₓ, and SiOₓN_{y}.

An inorganic opening OP422 corresponding to the first mask opening OP41 and the metal opening OP421 may be arranged in the inorganic layer 422. The inorganic opening OP422 may overlap the first mask opening OP41 in a plan view. The inorganic layer may include multiple inorganic openings OP422. For example, as shown in FIG. 3, the inorganic openings OP 422 may be arranged in the first direction (e.g., the y-axis direction) and the second direction (e.g., the x-axis direction).

A position of the inorganic opening OP422 may correspond to a position of the metal opening OP421. In a cross-sectional view, a width of the metal opening OP421 may be greater than a width of the inorganic opening OP422. In a plan view, an area of the metal opening OP421 may be greater than an area of the inorganic opening OP422. In a cross-sectional view, a thickness of the inorganic layer 422 may be greater than a thickness of the metal layer 421. The inorganic layer 422 may cover the metal layer 421. A portion of the metal layer 421 may be exposed from the inorganic layer 422. For example, a lower surface of the metal layer 421 may be exposed from the inorganic layer 422.

The inorganic layer 422 may include a first inorganic portion 4221 and a second inorganic portion 4222. The second inorganic portion 4222 may be disposed on the first inorganic portion 4221. The second inorganic portion 4222 may protrude toward the display substrate DS from the first inorganic portion 4221. The first inorganic portion 4221 and the second inorganic portion 4222 may be integrally provided as a single body.

The inorganic opening OP422 may include a first inorganic opening OP4221 arranged in the first inorganic portion 4221, and a second inorganic opening OP4222 arranged in the second inorganic portion 4222. The first inorganic opening OP4221 and the second inorganic opening OP4222 may be connected to each other. In a cross-sectional view, a width of the first inorganic opening OP4221 may gradually decrease in a third direction (e.g., a z-axis direction) facing the display substrate DS. In a plan view, an area of the second inorganic opening OP4222 may be greater than an area of the first inorganic opening OP4221. In other words, the width of the inorganic opening OP422 may gradually decrease in the third direction (e.g., the z-axis direction), and may increase at a boundary between the first inorganic opening OP4221 and the second inorganic opening OP4222. A step may be formed at the boundary between the first inorganic portion 4221 and the second inorganic portion 4222.

Due to an arrangement of the metal layer 421 having magnetic properties, the magnetic force portion MG (see FIG. 1) may apply a magnetic force to the mask assembly MA. In other words, an attractive force may be applied between the mask assembly MA and the magnetic force portion MG (see FIG. 1). Accordingly, the mask assembly MA and the display substrate DS may closely contact with each other. Due to the above, an error occurring in a process of depositing the display substrate DS may be reduced.

Due to the fact that the width of the metal opening OP421 is greater than the width of the inorganic opening OP422 in a cross-sectional view, an area in which the mask assembly MA and the display substrate DS contacting with each other may be reduced. A damage on the display substrate DS 6 due to a contact between the display substrate DS and the mask assembly MA may be reduced. Thus, quality of the display substrate DS and durability of the mask assembly MA may be improved.

Because the width of the first inorganic opening OP4221 gradually decreases in the third direction (e.g., the z-axis direction), a shadow phenomenon in which the deposition material M (see FIG. 1) is stuck in the mask assembly MA and does not reach the display substrate DS may be reduced. Accordingly, the quality of the display substrate DS may be improved.

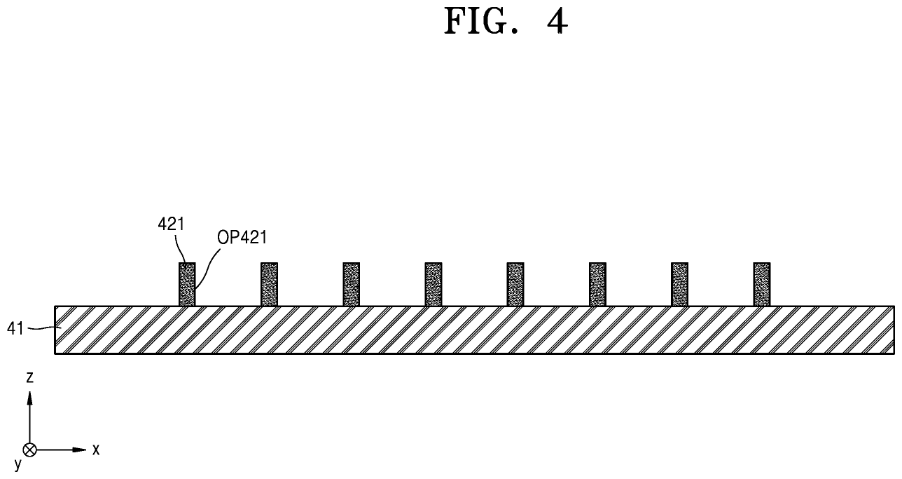

FIGS. 4 to 12 are schematic cross-sectional views of a mask assembly for describing a method of manufacturing a display device, according to an embodiment.

In FIGS. 4 to 12, the same reference symbols as those of FIGS. 1 to 3 denote the same members, and redundant descriptions thereof are omitted.

Referring to FIGS. 4 to 12, the method of manufacturing a display device may include arranging the mask assembly MA inside the chamber CH (see FIG. 1). The arranging of the mask assembly MA may include arranging, on the first mask layer 41, the metal layer 421 in which the metal opening OP421 is arranged, and arranging, on the metal layer 421, the inorganic layer 422 in which the inorganic opening OP422 is arranged.

Referring to FIG. 4, the arranging of the metal layer 421 in which the metal opening OP421 is arranged, on the first mask layer 41 may be identified. The arranging of the metal layer 421 in which the metal opening OP421 is arranged, on the first mask layer 41 may include disposing the metal layer 421 on the first mask layer 411, and forming the metal opening OP421 by etching the metal layer 421.

The metal layer 421 may be deposited on the first mask layer 41. The metal layer 421 may be etched by dry etching with an etching gas. The etching of the metal layer 421 may be performed through a photolithography process. After the metal layer 421 is etched, the metal opening OP421 may be formed in the metal layer 421.

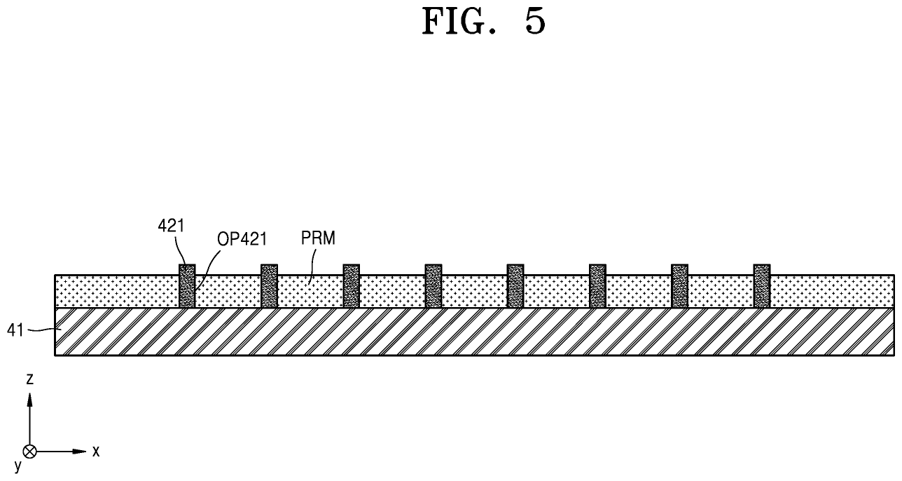

Referring to FIGS. 5 to 12, the arranging of the inorganic layer 422 in which the inorganic opening OP422 is arranged, on the metal layer 421 may include disposing a photoresist layer PRL on the first mask layer 41, disposing the inorganic layer 422 on the photoresist layer PRL, etching the inorganic layer 422, arranging the first mask opening in the first mask layer 41, and removing the photoresist layer PRL.

Referring to FIGS. 5 to 8, the disposing of the photoresist layer PRL on the first mask layer 411 may be identified.

Referring to FIG. 5, the disposing of the photoresist layer PRL on the first mask layer 41 may include disposing a photoresist material PRM on the first mask layer 41. The photoresist material PRM may be a photosensitive material. The photoresist material PRM may be arranged in the metal opening OP421 of the metal layer 421.

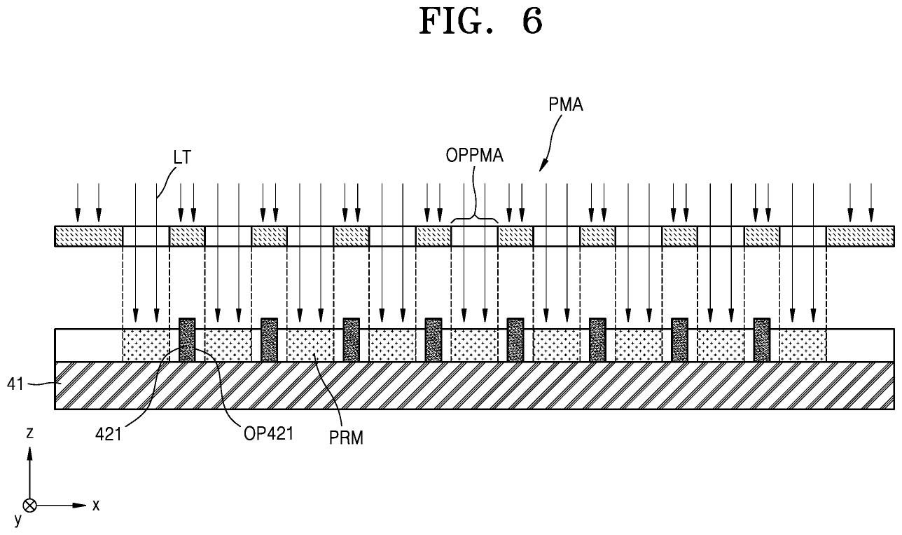

Referring to FIG. 6, the disposing of the photoresist layer PRL on the first mask layer 41 may include disposing, on the photoresist material PRM, a photomask PMA in which a photomask opening OPPMA is arranged, and exposing the photoresist material PRM through the photomask opening OPPMA.

The photomask opening OPPMA may overlap the metal opening OP421 of the metal layer 421 in a plan view. A position of the photomask opening OPPMA may correspond to the position of the metal opening OP421. A width of the photomask opening OPPMA may be less than the width of the metal opening OP421. Light LT may pass through the photomask opening OPPMA and may contact the photoresist material PRM. For example, the light LT may be ultraviolet rays. The photoresist material PRM overlapping the photomask opening OPPMA may decrease in solubility. The photoresist material PRM not overlapping the photomask opening OPPMA may increase in solubility.

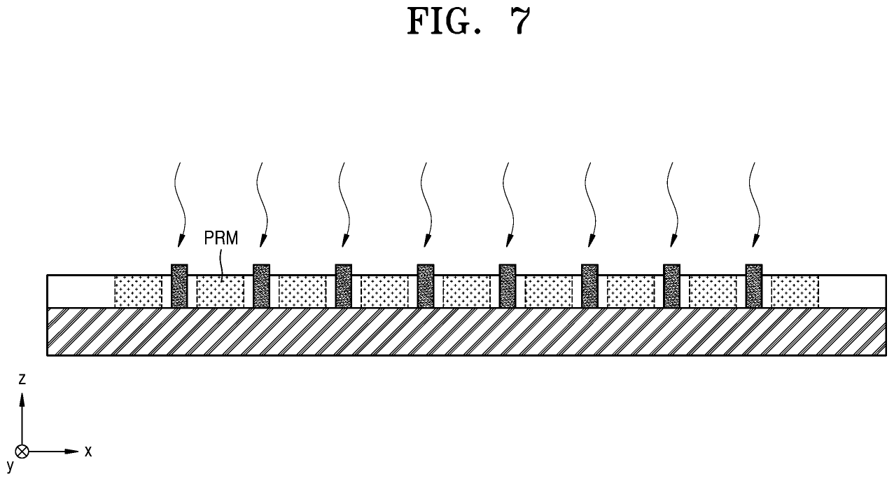

Referring to FIG. 7, the disposing of the photoresist layer PRL on the first mask layer 41 may include baking the photoresist material PRM by applying heat. The process of baking the photoresist material PRM may be a process of hardening the photoresist material PRM. A temperature for baking the photoresist material PRM may be in a range of about 0 degrees Celsius to about 125 degrees Celsius.

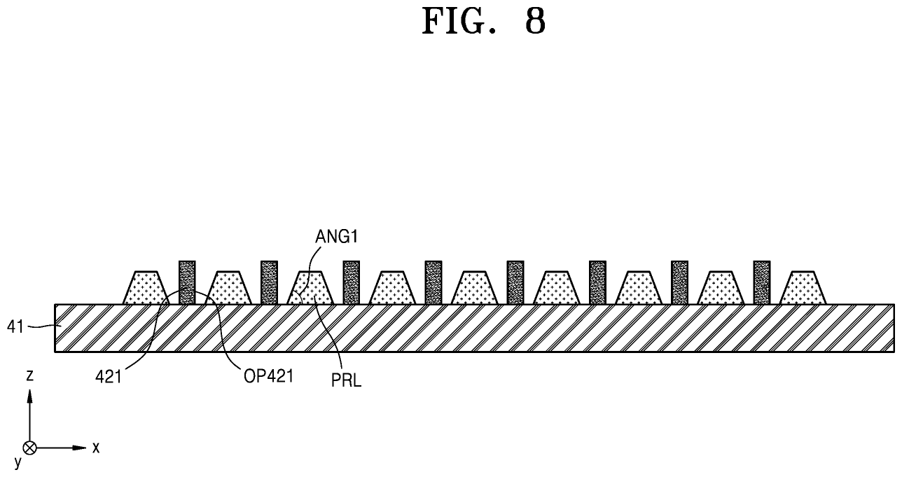

Referring to FIG. 8, the disposing of the photoresist layer PRL on the first mask layer 41 may include developing the photoresist material PRM into the photoresist layer PRL. The developing of the photoresist material PRM may include removing a portion of the photoresist material PRM by using an alkaline developer. The photoresist material PRM not contacting ultraviolet rays in FIG. 6 may be removed.

The photoresist layer PRL may be supported by the first mask layer 41 and may be arranged in the metal opening OP421 of the metal layer 421. A side surface of the photoresist layer PRL may be inclined with respect to an upper surface of the first mask layer 41 by a first angle ANG1. The first angle ANG1 may be determined according to the temperature of baking the photoresist material PRM described with reference to FIG. 7. As the temperature for baking the photoresist material PRM increases, the first angle ANG1 may decrease. Thus, the first angle ANG1 may be readily adjusted by controlling the baking temperature.

In FIGS. 5 to 8, a negative photoresist material of which the solubility decreases as the material contacts the light LT is used. However, the disclosure is not limited thereto, and in another embodiment, a positive photoresist material of which the solubility increases as the material contact the light LT may be used.

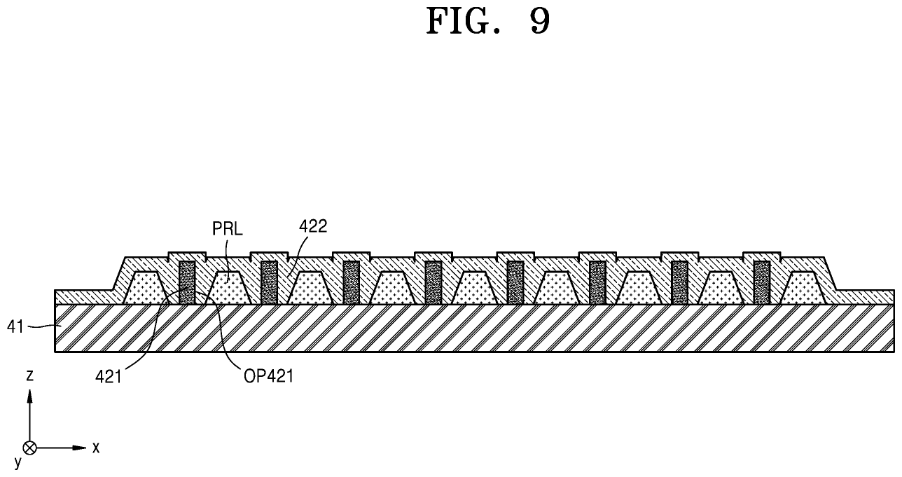

Referring to FIG. 9, the disposing of the inorganic layer 422 on the photoresist layer PRL may be identified. The inorganic layer 422 may cover the first mask layer 41, the metal layer 421, and the photoresist layer PRL. The inorganic layer 422 may be arranged in the metal opening OP421 of the metal layer 421.

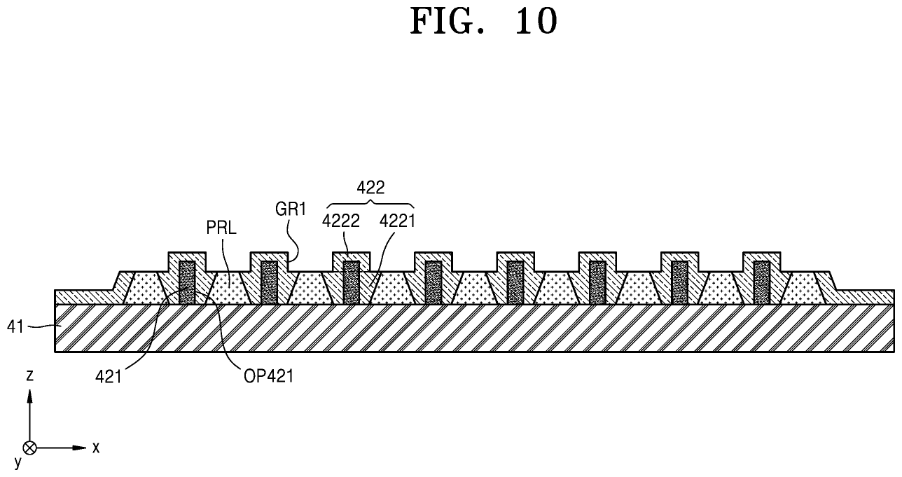

Referring to FIG. 10, etching of the inorganic layer 422 may be identified. The inorganic layer 422 may be etched by dry etching by an etching gas. The etching of the inorganic layer 422 may be performed through a photolithography process. After the inorganic layer 422 is etched, a first groove GR1 may be formed in the inorganic layer 422. The first groove GR1 may overlap the photoresist layer PRL in a plan view. Due to the first groove GR1, the photoresist layer PRL may be exposed from the inorganic layer 422. After the inorganic layer 422 is etched, the inorganic layer 422 may be divided into the first inorganic portion 4221 and the second inorganic portion 4222.

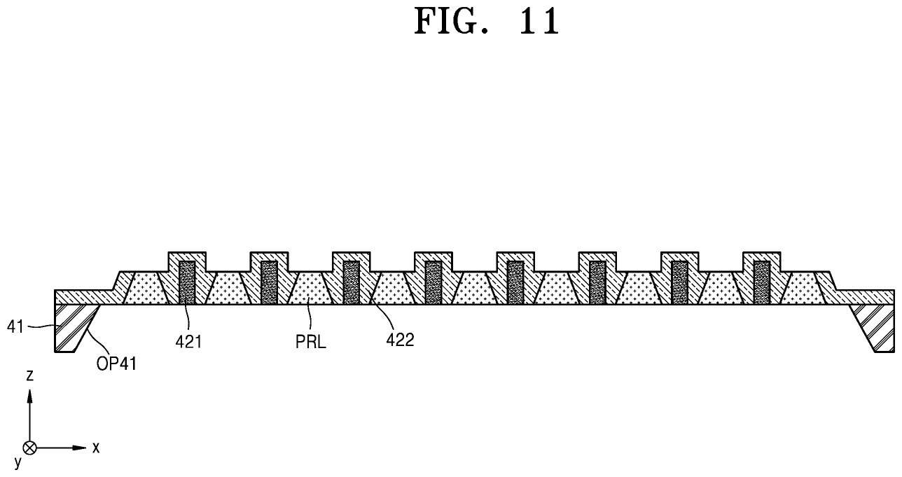

Referring to FIG. 11, the arranging of the first mask opening OP41 in the first mask layer 41 may be identified.

The first mask layer 41 may be etched by dry etching by an etching gas. The etching of the first mask layer 41 may be performed through a photolithography process. After the first mask layer 41 is etched, the first mask opening OP41 may be formed in the first mask layer 41. One first mask opening OP41 may be formed in the first mask layer 41, and the first mask opening OP41 may overlap the metal opening OP421 and the inorganic opening OP422 in a plan view.

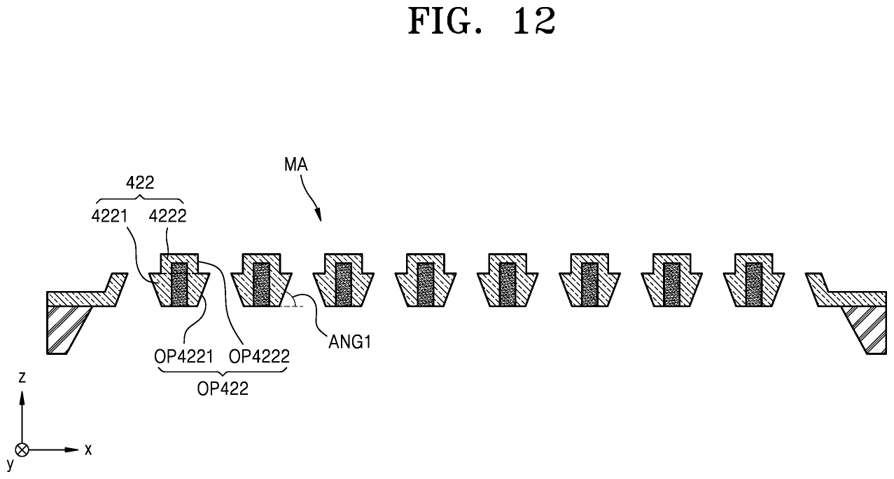

Referring to FIG. 12, the removing of the photoresist layer PRL (see FIG. 11) may be identified. For example, the photoresist layer PRL (see FIG. 11) remaining on the mask assembly MA may be removed by using a liquid resist stripper. As the photoresist layer PRL (see FIG. 11) is removed, the inorganic opening OP422 may be formed in the inorganic layer 422. In other words, the first inorganic opening OP4221 may be formed in the first inorganic portion 4221, and the second inorganic opening OP4222 may be formed in the second inorganic portion 4222.

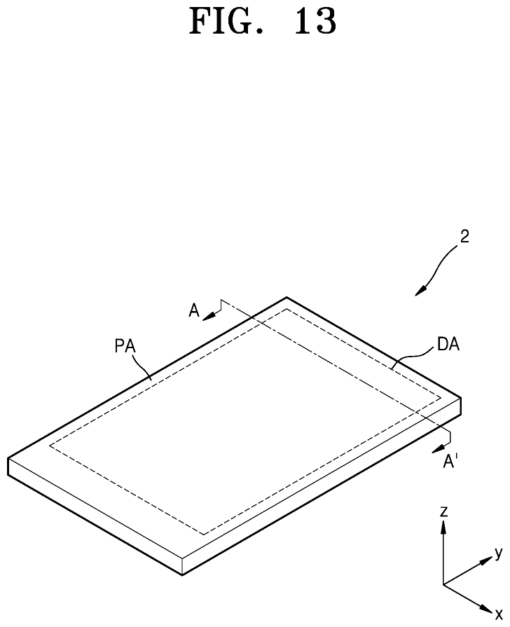

FIG. 13 is a schematic perspective view of a display device 2 according to an embodiment.

Referring to FIG. 13, the display device 2 may include a display area DA and a peripheral area PA disposed adjacent to the display area DA. The display device 2 may provide an image by using light emitted from multiple pixels arranged in the display area DA.

The peripheral area PA may surround an entire area of the display area DA. The peripheral area PA may be a non-display area in which pixels are not arranged, and a driver or lines configured to provide electrical signals or power to the pixels may be arranged in the peripheral area PA.

The display device 2 may have a rectangular shape in a plan view of which the width is longer than the length, as shown in FIG. 13, but the disclosure is not limited thereto. The display device 2 may have various shapes, such as a polygon, a circle, and an ellipse.

An organic light-emitting display device is described below as an embodiment of the display device 2. However, a display device of the disclosure is not limited thereto. In another embodiment, other types of display device, such as a quantum dot light-emitting display, may be used.

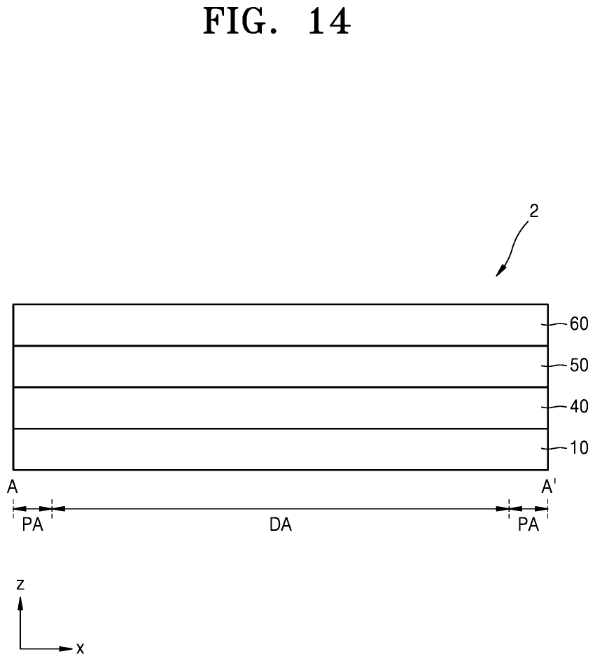

FIG. 14 is a schematic cross-sectional view of the display device 2 according to an embodiment. FIG. 14 may correspond to line A-A′ in FIG. 13.

Referring to FIG. 14, the display device 2 may include a display panel 10, an input sensing layer 40 disposed on the display panel 10, and an optical functional layer 50, which may be covered by a window 60. The display device 2 may be electronic equipment of various types, such as a mobile phone, a laptop computer, and a smartwatch.

An image may be displayed on the display panel 10. The display panel 10 may include pixels in the display area DA. Each of the pixels may include a display element and a pixel circuit connected thereto. The display element may include an organic light-emitting diode, or a quantum dot organic light-emitting diode.

The input sensing layer 40 may obtain coordinate information according to an external input, e.g., a touch event. The input sensing layer 40 may include a sensing electrode, or a touch electrode, and trace lines connected to the sensing electrode. The input sensing layer 40 may be disposed on the display panel 10. The input sensing layer 40 may sense the external input with a mutual cap method and/or a self-capacitance method.

The input sensing layer 40 may be formed directly on the display panel 10, or may be separately formed and bonded to the display panel 10 by an adhesive layer, such as an optical clear adhesive. For example, the input sensing layer 40 may be continuously formed after a process of forming the display panel 10, and the input sensing layer 4 may be a portion of the display panel 10, and an adhesive layer may not be formed between the input sensing layer 40 and the display panel 10. FIG. 14 illustrates that the input sensing layer 40 is located between the display panel 10 and the optical functional layer 50. However, the disclosure is not limited thereto, and in another embodiment, the input sensing layer 40 may be disposed on the optical functional layer 50.

The optical functional layer 50 may include an anti-reflection layer. The anti-reflection layer may reduce reflectivity of light (external light) incident toward the display panel 10 from the outside through the window 60. In an embodiment, the anti-reflection layer may include a black matrix and/or color filters. The color filters may be arranged according to a color of light emitted from each of the pixels.

In another embodiment, the anti-reflection layer may include a retarder and a polarizer. The retarder may be a film-type or liquid crystal coating-type retarder, and may include a λ/2 retarder and/or a λ/4 retarder. The polarizer may be a film-type or liquid crystal coating-type polarizer. The film type may include a stretchable synthetic resin film, and the liquid crystal coating type may include liquid crystals arranged in an array. Each of the retarder and the polarizer may include a protective film. The retarder and the polarizer themselves or the protective film may be defined as a base layer of the anti-reflection layer.

In another embodiment, the anti-reflection layer may include a destructive interference structure. The destructive interference structure may include a first reflection layer and a second reflection layer disposed in different layers. First reflected light and second reflected light respectively reflected from the first reflection layer and the second reflection layer may destructively interfere with each other, and accordingly, external light reflectivity may be reduced.

In an embodiment, the optical functional layer 50 may be continuously formed after a process of forming the display panel 10 and/or the input sensing layer 40. An adhesive layer may not be disposed between the optical functional layer 50, the display panel 10, and/or the input sensing layer 40.

Although not shown in FIG. 14, a layer including an optically clear adhesive or an optically clear resin may be located between the window 60 and the optical functional layer 50.

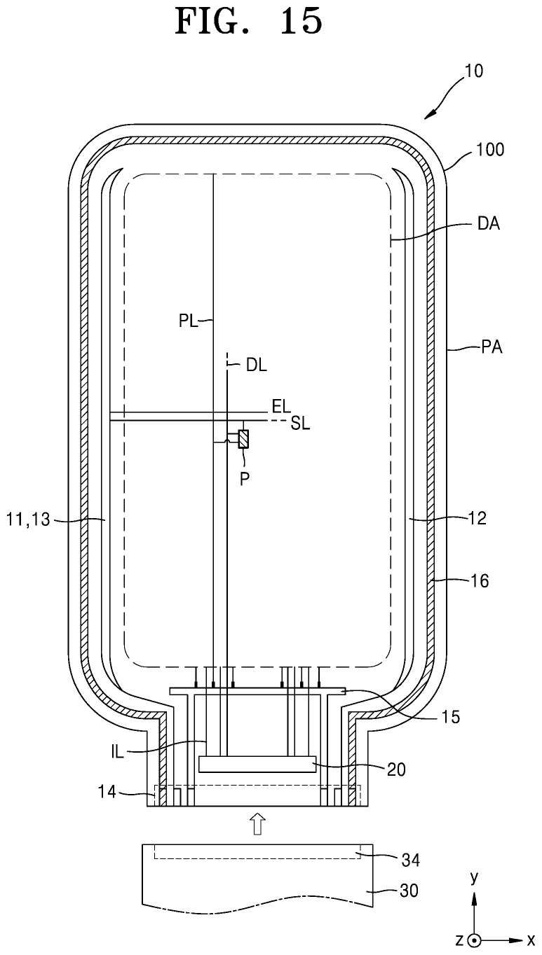

FIG. 15 is a schematic plan view of the display panel 10 according to an embodiment. As described with reference to FIG. 14, a display device according to an embodiment may include the display panel 10. FIG. 15 illustrates the substrate 100 of the display panel 10.

Referring to FIG. 15, the display panel 10 may include the display area DA and the peripheral area PA disposed adjacent to the display area DA. The display area DA may be an area on which an image is displayed, and multiple pixels P may be arranged in the display area DA. The display area DA may have various shapes in a plan view, such as a circle, an ellipse, a polygon, or a figure. FIG. 15 shows that the display area DA has an approximately rectangular shape having round edges.

Each of the pixels P may be a sub-pixel and may include a display element, such as an organic light-emitting diode. The pixel P may emit, for example, red, green, blue, or white light.

The peripheral area PA may be arranged adjacent to the display area DA. Outer circuits for driving the pixel P may be arranged in the peripheral area PA. A first scan driving circuit 11, a second scan driving circuit 12, an emission control driving circuit, a terminal 14, a driving power supply line 15, and a common power supply line 16 may be arranged in the peripheral area PA.

The first scan driving circuit 11 may provide a scan signal to the pixel P via a scan line SL. The second scan driving circuit 12 may be arranged to be parallel to the first scan driving circuit 11 with the display area DA interposed between the first scan driving circuit 11 and the second scan driving circuit 12. Some of the pixels P arranged in the display area DA may be electrically connected to the first scan driving circuits 11, and another one of the pixels P may be connected to the second scan driving circuit 12. In an embodiment, the second scan driving circuit 12 may be omitted, and the pixels P arranged in the display area DA may all be electrically connected to the first scan driving circuit 11.

The emission control driving circuit 13 may be arranged in the peripheral area PA on a side the first scan driving circuit 11 is arranged, and may provide an emission control signal to the pixel P via an emission control line EL. In FIG. 13, the emission control driving circuit 13 is arranged only at a side of the display area DA. However, the disclosure is not limited thereto, and the emission control driving circuit 13 may also be arranged at another side of the display area DA, similar to the first scan driving circuit 11 and the second scan driving circuit 12.

In an embodiment, the peripheral area PA may include a bending area extending from side of the display area DA (in a-y direction). The bending area may be bendable to a rear surface of the display area DA and may reduce an area of a non-display area, which is visible from a front surface of the display device.

A driving chip 20 may be arranged in the peripheral area PA. The driving chip 20 may include an integrated circuit for driving the display panel 10. The integrated circuit may be a data driving integrated circuit for generating a data signal, but the disclosure is not limited thereto.

The terminal 14 may be arranged in the peripheral area PA. The terminal 14 may be exposed without being covered by an insulating layer, and electrically connected to a printed circuit board 30. A terminal 34 of the printed circuit board 30 may be electrically connected to the terminal 14 of the display panel 30.

The printed circuit board 30 may transfer a signal or power of the controller (not shown) to the display panel 10. A control signal generated by the controller may be transferred to each of driving circuits via the printed circuit board 30. The controller may transfer a driving voltage ELVDD to the driving power supply line 15 and provide a common voltage ELVSS to the common power supply line 16. The driving voltage ELVDD may be transferred to each of the pixels P via a driving voltage line connected to the driving power supply line 15, and the common voltage ELVSS may be transferred to an opposite electrode of the pixel P connected to the common power supply line 16. The driving power supply line 15 may extend in a direction (an x-axis direction) at a lower side of the display region DA. The common power supply line 16 may have a loop shape in a plan view with a side open, and may partially surround the display area DA.

The controller may generate a data signal, and the generated data signal may be transmitted to an input line IL via the driving chip 20 and transmitted to the pixel P via a data line DL connected to the input line IL. The “line” may be a wire. This also applies to embodiments described below and modifications thereof.

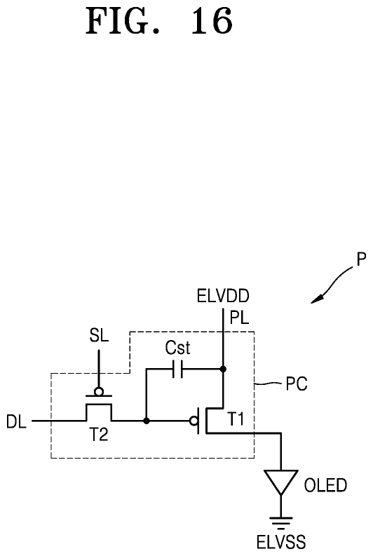

FIG. 16 is a schematic diagram of an equivalent circuit of a pixel P included in a display device according to an embodiment.

Referring to FIG. 16, the pixel P may include a pixel circuit PC and an organic light-emitting diode OLED, which is a display element connected to the pixel circuit PC. The pixel circuit PC may include a first thin-film transistor T1, a second thin-film transistor T2, and a storage capacitor Cst. For example, each of the pixels P may emit one of red, green, and blue light or one of red, green, blue, or white light via the organic light-emitting diode OLED.

The second thin-film transistor T2, which is a switching thin-film transistor, may be connected to the scan line SL and the data line DL, and may transfer a data voltage received via the data line DL to the first thin-film transistor T1 based on a switching voltage received via the scan line SL. The storage capacitor Cst may be connected to the second thin-film transistor T2 and the driving voltage line PL and may store a voltage corresponding to a voltage difference between the voltage received from the second thin-film transistor T2 and the driving voltage ELVDD applied to the driving voltage line PL.

The first thin-film transistor T1, which is a driving thin-film transistor, may be connected to the driving voltage line PL and the storage capacitor Cst and may control a driving current flowing to the organic light-emitting diode OLED from the driving voltage line PL corresponding to a voltage value stored in the storage capacitor Cst. The organic light-emitting diode OLED may emit light having a luminescence according to a driving current. An opposite electrode (e.g., a cathode) of the organic light-emitting diode OLED may receive the common voltage ELVSS.

FIG. 16 illustrates that the pixel circuit PC includes two thin-film transistors and one storage capacitor. However, the disclosure is not limited thereto. The number of thin-film transistors and the number of storage capacitors may be variously modified according to a design of the pixel circuit PC. For example, the pixel circuit PC may include four, five, or more thin-film transistors and more than one capacitor.

FIG. 17 is a schematic cross-sectional view of a display device according to an embodiment.

Referring to FIG. 17, the display panel 10 may include the substrate 100.

The substrate 100 may include a glass material or a polymer resin. In an embodiment, the substrate 100 may have a multi-layer structure in which a base layer including a polymer resin and a barrier layer for preventing permeation of external impurities are alternately stacked with each other.

The base layer may include a polymer resin including polyethersulfone (PES), polyarylate (PAR), polyetherimide (PEI), polyethylene naphthalate (PEN), polyethylene terephthalate (PET), polyphenylene sulfide (PPS), polyimide (PI), polycarbonate (PC), cellulose triacetate (TAC), cellulose acetate propionate (CAP), or a combination thereof.

The barrier layer may include an inorganic material, such as SiNₓ and SiOₓ.

In the display area DA of the substrate 100, a first pixel P1 emitting light of a first color, a second pixel P2 emitting light of a second color, and a third pixel P3 emitting light of a third color may be arranged. Each of the first color, the second color, and the third color may be one of red, blue, green, and white.

The first pixel P1 may include a first pixel circuit PC1 and a first organic light-emitting diode OLED, which is a display element electrically connected to the first pixel circuit PC1. The second pixel P2 may include a second pixel circuit PC2 and a second organic light-emitting diode OLED2 electrically connected to the second pixel circuit PC2. The third pixel P3 may include a third pixel circuit PC3 and a third organic light-emitting diode OLED3 electrically connected to the third pixel circuit PC3.

A buffer layer 201 may be formed on the substrate 100 to prevent permeation of impurities into a semiconductor layer Act of a thin-film transistor TFT of the first pixel circuit PC1, the second pixel circuit PC2, and the third pixel circuit PC3. The buffer layer 201 may include an inorganic insulating such as SiNₓ, SiON, and SiOₓ, and may have a single layer or multiple layers including the inorganic insulating material described above.

The first pixel circuit PC1, the second pixel circuit PC2, and the third pixel circuit PC3 may be disposed on the buffer layer 201. The first pixel circuit PC1 may include a thin-film transistor TFT and a storage capacitor Cst. The thin-film transistor TFT may include a semiconductor layer Act, a gate electrode GE, a source electrode SE, and a drain electrode DE. The thin-film transistor TFT shown in FIG. 17 may correspond to the first thin-film transistor described with reference to FIG. 16. Although not shown in FIG. 17, the data line DL may be electrically connected to a second thin-film transistor included in the first pixel circuit PC1. In an embodiment, the thin-film transistor TFT may be a top gate type in which the gate electrode GE is disposed on the semiconductor layer Act with a gate insulating layer 203 interposed between the gate electrode GE and the semiconductor layer Act. However, the disclosure is not limited thereto, and according to another embodiment, the thin-film transistor TFT may be a bottom gate type. Each of the second pixel circuit PC2 and the third pixel circuit PC3 may have the same or similar structure as or to the first pixel circuit PC1. Each of elements of the first pixel circuits PC1 is described below.

The semiconductor layer Act may include polysilicon. In another embodiment, the semiconductor layer Act may include amorphous silicon, oxide semiconductor, an organic semiconductor, or the like. The gate electrode GE may include a low-resistance metal material. The gate electrode GE may include a conductive material such as Al, Cu, and Ti, and may have a multi-layer or a single-layer including the material described above.

The gate insulating layer 203 between the semiconductor layer Act and the gate electrode GE may include an inorganic insulating material, such as SiOₓ, SiNₓ, silicon oxynitride (SiON), aluminum oxide (Al₂O₃), titanium oxide (TiOₓ), tantalum oxide (Ta₂O₅), and hafnium oxide (HfO₂). The gate insulating layer 203 may have a single layer or multiple layers including the material described above.

The storage capacitor Cst may include a lower electrode CE1 and an upper electrode CE2, which overlap each other in a plan view with a first interlayer insulating layer 205 between the lower electrode CE and the upper electrode CE2. The storage capacitor Cst may overlap the thin-film transistor TFT in a plan view. Referring to FIG. 17, the gate electrode GE of the thin-film transistor TFT may be the lower electrode CE1 of the storage capacitor Cst. In another embodiment, the storage capacitor Cst may not overlap the thin-film transistor TFT. The storage capacitor Cst may be covered by a second interlayer insulating layer 207. The upper electrode CE2 of the storage capacitor Cst may include a conductive material such as Aal, Cu, and Ti, and may have multiple layers or a single layer including the material described above.

Each of the first interlayer insulating layer 205 and the second interlayer insulating layer 207 may include an inorganic insulating material, such as SiOₓ, SiNₓ, SiON, Al₂O₃, TiOₓ, Ta₂O₅, and HfO₂. Each of the first interlayer insulating layer 205 and the second interlayer insulating layer 207 may have a single layer or multiple layers including the material described above.

The source electrode SE, the drain electrode DE, and the data line DL may be disposed in a same layer, and may include a same material. For example, the source electrode SE, the drain electrode DE, and the data line DL may be located on the second interlayer insulating layer 207. Each of the source electrode SE, the drain electrode DE, and the data line DL may include a material having good conductivity. Each of the source electrode SE and the drain electrode DE may include a conductive material such as Mo, Al, Cu, and Ti, and may have multiple layers or a single layer including the material described above. In an embodiment, each of the source electrode SE, the drain electrode DE, and the data line DL may include multiple layers of Ti/Al/Ti.

The first pixel circuit PC1, the second pixel circuit PC2, and the third pixel circuit PC3, which each include the thin-film transistor TFT and the storage capacitor Cst, may be covered by a first organic insulating layer 209. The first organic insulating layer 209 may have an approximately flat upper surface.

The first organic light-emitting diode OLED1 electrically connected to the first pixel circuit PC1, the second organic light-emitting diode OLED2 electrically connected to the second pixel circuit PC2, and the third organic light-emitting diode OLED3 electrically connected to the third pixel circuit PC3 may be located on the first organic insulating layer 209.

The first pixel circuit PC1 may be electrically connected to a first pixel electrode 221r of the first organic light-emitting diode OLED1. For example, as shown in FIG. 17, a contact metal layer CM may be located between the thin-film transistor TFT and the first pixel electrode 221r. The contact metal layer CM may be in contact with the thin-film transistor TFT via a contact hole passing through the first organic insulating layer 209, and the first pixel electrode 221r may be in contact with the contact metal layer CM via a contact hole passing through a second organic insulating layer 211 on the contact metal layer CM. The contact metal layer CM may include a conductive material such as Mo, Al, Cu, and Ti, and may have multiple layers or a single layer including the material described above. In an embodiment, the contact metal layer CM may include multiple layers of Ti/Al/Ti.

Each of the first organic insulating layer 209 and the second organic insulating layer 211 may include an organic insulating material, such as a general-purpose polymer, such as poly(methyl methacrylate) (PMMA) or polystyrene (PS), a polymer derivative having a phenol-based group, an acryl-based polymer, an imide-based polymer, an aryl ether-based polymer, an amide-based polymer, a fluorine-based polymer, a p-xylene-based polymer, a vinyl alcohol-based polymer, or a blend thereof. In an embodiment, each of the first organic insulating layer 209 and the second organic insulating layer 211 may include polyimide.

According to another embodiment, one of the first organic insulating layer 209 and the second organic insulating layer 211 may be omitted, and the contact metal layer CM may be omitted.

The first organic light-emitting diode OLED1 may include the first pixel electrode 221r, a first emission layer 222r, and a first opposite electrode 223r. The second organic light-emitting diode OLED2 may include a second pixel electrode 221g, a second emission layer 222g, and a second opposite electrode 223g. The third organic light-emitting diode OLED3 may include a third pixel electrode 221b, a third emission layer 222b, and a third opposite electrode 223b. Each of the second organic light-emitting diode OLED2 and the third organic light-emitting diode OLED3 may have a similar or identical structure to the first organic light-emitting diode OLED1.

The first pixel electrode 221r may be disposed on the second organic insulating layer 211. The first pixel electrode 221r may include a conductive oxide, such as indium tin oxide (ITO), indium zinc oxide (IZO), zinc oxide (ZnO), indium oxide (In2O3), indium gallium oxide (IGO), or aluminum zinc oxide (AZO). In another embodiment, the first pixel electrode 221r may include a reflective film including silver (Ag), magnesium (Mg), Al, platinum (Pt), palladium (Pd), gold (Au), nickel (Ni), neodymium (Nd), iridium (Ir), chromium (Cr), or a compound thereof. In another embodiment, the first pixel electrode 221r may further include a film including ITO, IZO, ZnO, or In₂O₃, on/under the reflective film described above.

A pixel-defining layer 213 and a bank layer 215 may be disposed on the first pixel electrode 221r. The pixel-defining layer 213 may overlap an edge of the first pixel electrode 221r in a plan view. The pixel-defining layer 213 may include an inorganic insulating material, such as SiNₓ, SiON, or SiOₓ.

A first residual sacrificial layer 212R may be disposed between the first pixel electrode 221r and the pixel-defining layer 213. The first residual sacrificial layer 212R may be a portion that remains after a sacrificial layer for protecting an upper surface of the first pixel electrode 221r is removed. The first residual sacrificial layer 212R may be disposed in an area overlapping the pixel-defining layer 213 and the first pixel electrode 221r in a plan view. For example, the first residual sacrificial layer 212R may be arranged along an edge of the first pixel electrode 221r and expose a central portion of the first pixel electrode 221r.

The first residual sacrificial layer 212R may be continuously formed with the first pixel electrode 221r, and may include a material that is selectively etchable without damaging the first pixel electrode 221r. For example, the first residual sacrificial layer 212R may include indium gallium zinc oxide (IGZO) and/or IZO.

The first residual sacrificial layer 212R and the pixel-defining layer 213 may overlap the edge of the first pixel electrode 221r in a plan view and increase a distance between the first pixel electrode 221r and each of the bank layer 215 and the first opposite electrode 223r, so that an arc may be prevented from occurring therebetween. In embodiments, a sacrificial layer may be completely removed, and the first residual sacrificial layer 212R may not be formed. A groove generated by removing the sacrificial layer between the first pixel electrode 221r and the pixel-defining layer 213 may be empty or may be buried by the first emission layer 222r described below.

The bank layer 215 may be disposed on the pixel-defining layer 213. The bank layer 215 may include a conductive material. For example, the bank layer 215 may include a conductive material such as Mo, Al, Cu, and Ti, and may have multiple layers or a single layer including the material described above. For example, the bank layer 215 may have a double-layer structure of Al/Ti, or may have a three-layer structure of Ti/Al/Ti.

Each of the pixel-defining layer 213 and the bank layer 215 may extend from the display area DA of the substrate 100 to the peripheral area PA (see FIG. 15), and the bank layer 215 may be directly contact the common power supply line 16 (see FIG. 15) located in the peripheral area PA (see FIG. 15) via an opening of the pixel-defining layer 213. Accordingly, the bank layer 215 may function as a connection electrode or an auxiliary line for transferring the common voltage to the first opposite electrode 223r, the second opposite electrode 223g, and the third opposite electrode 223b.

A first conductive layer 217 may be located on the bank layer 215. The first conductive layer 217 may have a tip 217T protruding in a direction from a center of the first pixel electrode 221r. In a plan view, the tip 217T of the first conductive layer 217 may have a loop shape completely surrounding the first pixel electrode 221r.

The first opening OP1 may expose a central portion of the upper surface of the first pixel electrode 221r through the pixel-defining layer 213, the bank layer 215, and the first conductive layer 217, and the first emission layer 222r described below may overlap and expose the first pixel electrode 221r through the first opening OP1 in a plan view. Accordingly, the first opening OP1 may define a first emission area EA1. An outer side of the first emission area EA1 may be defined as a non-emission area NEA. Similarly, a second opening OP2 may define a second emission area EA2, and a third opening OP3 may define a third emission area EA3.

A portion of the first conductive layer 217 may be spaced apart from the bank layer 215 in a direction (the z-axis direction) perpendicular to the substrate 100 and may form the tip 217T protruding in a direction from the center of the first pixel electrode 221r. Because the tip 217T of the first conductive layer 217 is formed by removing a portion of a sacrificial layer located between the first conductive layer 217 and the bank layer 215, the first conductive layer 217 may have an undercut structure. Accordingly, the tip 217T of the first conductive layer 217 may form an eaves structure in which a lower surface of the first conductive layer 217 is exposed. A protrusion length d1 of the tip 217T of the first conductive layer 217 may be greater than or equal to about 0.5 μm. In embodiments, the protrusion length d1 of the tip 217T of the first conductive layer 217 may be in a range of about 0.3 μm to about 1 μm. In embodiments, the protrusion length d1 of the tip 217T of the first conductive layer 217 may be in a range of about 0.3 μm to about 0.7 μm.

The first conductive layer 217 may include a conductive material. For example, the first conductive layer 217 may include a conductive material such as Mo, Al, Cu, and Ti, and may have a single layer or multiple layers including the material described above. For example, the first conductive layer 217 may have a double-layer structure of Al/Ti, or may have a three-layer structure of Ti/Al/Ti.

In an embodiment, a low-reflective layer (not shown) may be located on the first conductive layer 217. The low-reflective layer may be a layer having a surface reflectivity lower than a surface reflectivity of the first conductive layer 217. The low-reflective layer may prevent light (external light) incident toward the display device 2 from being reflected on a surface of the first conductive layer 217 and visible to a user of the display device 2.

In an embodiment, the low-reflective layer may include a low-reflective material. The low-reflective material may include a metal oxide having a high light absorptivity, i.e., a high extinction coefficient (k). For example, the low-reflective layer may include at least one of copper oxide (CuO), calcium oxide (CaO), molybdenum oxide (MoOx), and ZnO. In embodiments, the low-reflective layer may include CuO and CaO.

A second residual sacrificial layer 214R may be disposed between the first conductive layer 217 and the bank layer 215. The second residual sacrificial layer 214R may be a remaining portion of the sacrificial layer that is removed to form the tip 217T of the first conductive layer 217. In a plan view, the second residual sacrificial layer 214R may be spaced apart from the first pixel electrode 221r by a distance and may have a loop shape completely surrounding the first pixel electrode 221r. By the second residual sacrificial layer 214R, the first conductive layer 21 may have an undercut structure.

The second residual sacrificial layer 214R may determine the protrusion length d1 of the tip 217T of the first conductive layer 217. For example, the second residual sacrificial layer 214R may be located more inward than an end of the tip 217T of the first conductive layer 217, and the protrusion length d1 of the tip 217T may be a length from a sidewall of the second residual sacrificial layer 214R to the end of the tip 217T.

The second residual sacrificial layer 214R may include a material that is selectively etchable without damaging the first pixel electrode 221r, the bank layer 215, and the first conductive layer 217. For example, the second residual sacrificial layer 214R and the first residual sacrificial layer 212R may include a same material. In an embodiment, the second residual sacrificial layer 214R may include IGZO and/or IZO.

The first emission layer 222r may be disposed on the first pixel electrode 221r and the first conductive layer 217. For example, the first emission layer 222r may contact the first pixel electrode 221r through the first opening OP1. The first pixel electrode 221r may include a polymer or low-molecular weight organic material emitting light of a first color (e.g., red). In another embodiment, the first emission layer 222r may include an inorganic material or quantum dots.

The first emission layer 222r may include a first functional layer (not shown) and a second functional layer (not shown) on or under the first functional layer. The first functional layer may include a hole transport layer (HTL) and/or a hole injection layer (HIL). The second functional layer may include an electron transport layer (ETL) and/or an electron injection layer (EIL).

FIG. 17 illustrates that the display device includes an emission layer with a single stack structure. However, the disclosure is not limited thereto, and in embodiments, the display device 2 may have a tandem structure, which is a multi-stack structure including multiple emission layers. In case that the display device 2 has a tandem structure, a charge generation layer (CGL) may be arranged between the emission layers.

The first emission layer 222r may be disconnected from a dummy portion 222rp by the tip 217T of the first conductive layer 217. The first emission layer 222r and the dummy portion 222rp may include a same material and/or a same number of sub-layers (e.g., a first functional layer, a second functional layer, and the like).

The first emission layer 222r may have at least one first hole 222rh exposing a portion of an upper surface of the first conductive layer 217.

The second emission layer 222g may include a polymer or low-molecular weight organic material emitting light of a second color (e.g., green), and the third emission layer 222b may include a polymer or low-molecular weight organic material emitting light of a third color (e.g., blue).

The first opposite electrode 223r may be disconnected from the dummy portion 223rp by the tips 217T of the first conductive layer 217. The first opposite electrode 223r and the dummy portion 223rp may include a same material.

The opposite electrode 223r may include a (semi-)transparent layer including Ag, Mg, Al, Pt, Pd, Au, Ni, Nd, Ir, Cr, Li, Ca, or an alloy thereof. In an embodiment, the first opposite electrode 223r may further include a layer including ITO, IZO, ZnO, or In₂O₃, on the (semi-)transparent layer.

A first inorganic encapsulation layer 311 may be disposed on the first opposite electrode 223r. The first inorganic encapsulation layer 311 may have a step coverage and may thus cover at least a portion of an exposed lower surface of the tip 217T of the first conductive layer 217. For example, the first inorganic encapsulation layer 311 may be continuously formed to cover upper and side surfaces of the first opposite electrode 223r, a side surface of the first emission layer 222r, side and lower surfaces of the tip 217T of the first conductive layer 217, a side surface of the second residual sacrificial layer 214R, and an upper surface of the bank layer 215.

The first inorganic encapsulation layer 311 may include an inorganic insulating material, such as SiNₓ, SiON, and SiOₓ. The first inorganic encapsulation layer 311 may be in direct contact with a metal surface on the side and lower surfaces of the tip 217T of the first conductive layer 217, and may form an inorganic contact area ICR. Accordingly, the inorganic contact area ICR may form a closed loop completely surrounding the first organic light-emitting diode OLED and reduce or block a passage through which impurities, such as moisture and/or air, permeate.

As shown in FIG. 17, the second inorganic encapsulation layer 312 may seal the second organic light-emitting diode OLED2, and the third inorganic encapsulation layer 313 may seal the third organic light-emitting diode OLED3. Because the first inorganic encapsulation layer 311, the second inorganic encapsulation layer 312, and the third inorganic encapsulation layer 313 constitute an inorganic contact area in the display area DA, an inorganic contact area in the peripheral area PA (see FIG. 15) necessary for reducing peeling defects due to the emission layer may be reduced. Because an organic light-emitting diode is sealed in units of pixels, even in case that a passage through which impurities, such as moisture and/or air, permeate occurs in one pixel or at a boundary of the substrate 100, defects of the passage may be prevented from propagating to neighboring pixels.

An organic planarization layer 410 may be arranged to cover the first inorganic encapsulation layer 311, the second inorganic encapsulation layer 312, and the third inorganic encapsulation layer 313. The organic planarization layer 410 may cover unevenness due to the pixel-defining layer 213, the bank layer 215, and the first conductive layer 217, and provide a flat surface to elements disposed on the organic planarization layer 410. The organic planarization layer 410 may include a polymer-based material. For example, the organic planarization layer 410 may include an acryl-based resin, an epoxy-based resin, polyimide, polyethylene, or the like.

In an embodiment, a refractive index of the organic planarization layer 410 may be greater than each of refractive indices of the first inorganic encapsulation layer 311, the second inorganic encapsulation layer 312, and the third inorganic encapsulation layer 313. For example, the refractive index of the organic planarization layer 41 may be greater than or equal to about 1.6. The refractive index of the organic planarization layer 410 may be in a range of about 1.6 to about 1.9. The organic planarization layer 410 may further include dispersion particles with a high refractive index. For example, the organic planarization layer 410 may include metal oxide particles including zinc oxide (ZnOₓ), titanium oxide (TiO₂), zirconium oxide (ZrO₂), and barium titanium oxide (BaTiO₃) dispersed in the organic planarization layer 410.

A protective layer 420 may be disposed on the organic planarization layer 410. The protective layer 420 may include an inorganic insulating material, such as SiNₓ, SiON, and SiOₓ. In an embodiment, a refractive index of the protective layer 420 may be less than the refractive index of the organic planarization layer 410.

An anti-reflection layer 500 including a first color filter 510, a second color filter 520, a third color filter 530, a light-shielding layer 540, and an overcoat layer 550 may be disposed on the protective layer 420. The anti-reflection layer 500 may reduce reflectivity of light (external light) incident to the display device 2 from the outside.

The light-shielding layer 540 may overlap the bank layer 215 and the first conductive layer 217 in a plan view, and may at least partially absorb reflected light by the bank layer 215 and the first conductive layer 217, in the non-display area NEA. The non-emission area NEA may be an area not overlapping the first emission area EA1, the second emission area EA2, and the third emission area EA3 in a plan view. The light-shielding layer 540 may include black pigment. The light-shielding layer 540 may be a black matrix. The light-shielding layer 540 may have a first filter opening 540OP1 corresponding to the first emission area EA1, a second filter opening 540OP2 corresponding to the second emission area EA2, and a third filter opening 540OP3 corresponding to the third emission area EA3.

The first color filter 510 may be disposed in the first filter opening 540OP1 corresponding to the first emission layer 222r. The first color filter 510 may selectively transmit light emitted from the first emission layer 222r. For example, the first color filter 510 shown in FIG. 17 may be a red color filter for transmitting red light.

The second color filter 520 may be disposed in the second filter opening 540OP2 corresponding to the second emission layer 222g. The second color filter 520 may selectively transmit light emitted from the second emission layer 222g. The third color filter 530 may be disposed in the third filter opening 540OP3 corresponding to the third emission layer 222b. The third color filter 530 may selectively transmit light emitted from the third emission layer 222b. For example, the second color filter 520 shown in FIG. 17 may be a green color filter for transmitting green light, and the third color filter 530 may be a blue color filter for transmitting blue light.

The overcoat layer 550 may be disposed on the first to third color filters 510, 520, and 530. The overcoat layer 550, which is a light-transmitting layer, may cover unevenness due to the first to third color filters 510, 520, and 530 and the light-shielding layer 540 and provide a flat upper surface. The overcoat layer 550 may include a colorless light-transmitting organic material, such as an acryl-based resin.

According to an embodiment, in an apparatus for manufacturing a display device, a manufacturing speed may be improved, a phenomenon in which a display substrate is damaged may be reduced, and durability of a mask assembly may be improved.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. An apparatus for manufacturing a display device, the apparatus comprising:
a chamber;
a mask assembly arranged inside the chamber and facing a display substrate;
a magnetic force portion arranged inside the chamber and applying a magnetic force to the mask assembly; and
a deposition source which is arranged inside the chamber, faces the mask assembly, and supplies a deposition material that passes through the mask assembly and is deposited on the display substrate, wherein
the mask assembly includes:
a first mask layer including a first mask opening; and
a second mask layer disposed on the first mask layer,
the second mask layer includes:
a metal layer including a metal opening corresponding to the first mask opening; and
an inorganic layer including an inorganic opening corresponding to the first mask opening and the metal opening, and
in a plan view, a width of the metal opening is greater than a width of the inorganic opening.

2. The apparatus of claim 1, wherein the inorganic layer covers the metal layer.

3. The apparatus of claim 2, wherein a portion of the metal layer is exposed from the inorganic layer.

4. The apparatus of claim 1, wherein
the inorganic layer includes:
a first inorganic portion; and
a second inorganic portion disposed on the first inorganic portion, and
the inorganic opening includes:
a first inorganic opening arranged in the first inorganic portion; and
a second inorganic opening arranged in the second inorganic portion.

5. The apparatus of claim 4, wherein, in a plan view, an area of the second inorganic opening is greater than an area of the first inorganic opening.

6. The apparatus of claim 4, wherein, in a cross-sectional view, a width of the first inorganic opening gradually decreases in a direction toward the second inorganic portion.

7. A method of manufacturing a display device, the method comprising:
arranging a display substrate inside a chamber;
arranging a mask assembly inside the chamber;
applying, by a magnetic force portion, a magnetic force to the mask assembly; and
supplying, by a deposition source, a deposition material toward the mask assembly, wherein
the arranging of the mask assembly includes:
arranging, on a first mask layer, a metal layer including a metal opening; and
arranging, on the metal layer, an inorganic layer including an inorganic opening, and,
in a plan view, a width of the metal opening is greater than a width of the inorganic opening.

8. The method of claim 7, wherein the arranging of the inorganic layer includes:
arranging a photoresist layer on the first mask layer;
arranging the inorganic layer on the photoresist layer;
etching the inorganic layer; and
removing the photoresist layer.

9. The method of claim 8, wherein the arranging of the photoresist layer includes:
arranging a photoresist material on the first mask layer;
arranging, on the photoresist material, a photomask including a photomask opening;
exposing the photoresist material to light through the photomask opening; and
developing the photoresist material.

10. The method of claim 9, wherein the arranging of the photoresist layer further includes baking the photoresist material.

11. The method of claim 7, wherein the inorganic layer covers the metal layer.

12. The method of claim 11, wherein a portion of the metal layer is exposed from the inorganic layer.

13. The method of claim 7, wherein
the inorganic layer includes:
a first inorganic portion; and
a second inorganic portion disposed on the first inorganic portion, and
the inorganic opening includes:
a first inorganic opening arranged in the first inorganic portion; and
a second inorganic opening arranged in the second inorganic portion.

14. The method of claim 13, wherein, in a plan view, an area of the second inorganic opening is greater than an area of the first inorganic opening.

15. The method of claim 14, wherein, in a cross-sectional view, a width of the first inorganic opening gradually decreases in a direction toward the second inorganic portion.

16. A mask assembly comprising:
a first mask layer including a first mask opening; and
a second mask layer disposed on the first mask layer, wherein
the second mask layer includes:
a metal layer including a metal opening corresponding to the first mask opening; and
an inorganic layer including an inorganic opening corresponding to the first mask opening and the metal opening, and,
in a plan view, a width of the metal opening is greater than a width of the inorganic opening.

17. The mask assembly of claim 16, wherein
the inorganic layer includes:
a first inorganic portion; and
a second inorganic portion disposed on the first inorganic portion, and
the inorganic opening includes:
a first inorganic opening arranged in the first inorganic portion; and
a second inorganic opening arranged in the second inorganic portion.

18. The mask assembly of claim 17, wherein, in a plan view, an area of the second inorganic opening is greater than an area of the first inorganic opening.

19. The mask assembly of claim 17, wherein, in a cross-sectional view, a side of the first inorganic opening is inclined.

20. The mask assembly of claim 16, wherein the inorganic layer covers the metal layer.
